(19) United States
(12) Patent Application Publication
(10) Pub. No.: US 2014/0339700 A1
(43) Pub. Date: Nov. 20, 2014

(54) GRAPHENE-BASED METAL DIFFUSION BARRIER

(71) Applicant: UNIVERSITY OF FLORIDA RESEARCH FOUNDATION, INC., GAINESVILLE, FL (US)

(72) Inventors: Fan Ren, Gainesville, FL (US); Stephen John Pearton, Gainesville, FL (US); Jihyun Kim, Seoul (KR); Hong-Yeol Kim, Seoul (KR)

(21) Appl. No.: 14/367,637

(22) PCT Filed: Dec. 18, 2012
(86) PCT No.: PCT/US12/70278

§ 371 Date: Jun. 20, 2014

Related U.S. Application Data
(60) Provisional application No. 61/577,870, filed on Dec. 20, 2011.

(51) Int. Cl. H01L 23/532; H01L 21/768; H01L 21/285

(52) U.S. Cl. CPC H01L 23/53276; H01L 21/28562; H01L 21/7685; H01L 23/53223; H01L 23/53252
USPC 257/751; 438/653

(57) ABSTRACT

Contacts for semiconductor devices are formed where a barrier layer comprising graphene is situated between a first layer comprising a conductor, and a second layer comprising a second conductor or a semiconductor. For example, a metal layer can be formed on a graphene layer residing on a semiconductor. The barrier layer can be directly formed on some second layers, for example, graphene can be transferred from an organic polymer/graphene bilayer structure and the organic polymer removed and replaced with a metal or other conductor that comprises the first layer of the contact. The bilayer can be formed by CVD deposition on a metallic second layer, or the graphene can be formed on a template layer, for example, a metal layer, and bound by a binding layer comprising an organic polymer to form an organic polymer/graphene/metal trilayer structure. The template layer can be removed to yield the bilayer structure. Contacts with the graphene barrier layer display enhanced reliability as the graphene layer inhibits diffusion and reaction between the layers contacting the barrier layer.

### CROSS-REFERENCE TO RELATED APPLICATION

The present application claims the benefit of U.S. Provisional Application Ser. No. 61/577,870, filed Dec. 20, 2011, which is hereby incorporated by reference herein in its entirety, including any figures, tables, or drawings.

### BACKGROUND OF INVENTION

Graphene has attracted a lot of attention due to its superior properties. Graphene is a semimetal where charge carriers behave as Dirac fermions (zero effective mass), displaying mobilities up to 200,000 cm²V⁻¹s⁻¹, ballistic transport distances of up to a micron at room temperature, half-integer quantum Hall effect, and absorption of only 2.3% of visible light. Because of the large carrier mobilities, graphene is attractive for high frequency electronic devices. Graphene's low absorbance and semi-metallic nature suggests an ideal transparent conductor. Increasing efforts are directed to the use of graphene and related materials, such as highly oriented graphite, which is essentially a stack of graphene bilayers, to form stable rectifying contacts on semiconductors, such as Si, GaAs and SiC. Graphene has been shown to be an effective oxidation barrier on Cu and Cu/Ni, preventing air oxidation of the metals at elevated temperatures.

The promise of graphene based devices has sparked a significant amount of research directed to the deposition of high quality uniform thin graphene films having a controlled thickness over a large area. To date, the highest quality graphene has been achieved by mechanical cleavage of highly oriented pyrolytic graphite. Although this pristine graphene has very low concentration of structural defects, flake thickness, size and location can not be controlled. One route to large scale uniform graphene has been by covalent or non-covalent liquid phase exfoliation of graphite. However, these methods introduce structural and electronic disorder in the graphene. Another route is by the conversion of SiC(0001) to graphene via high temperature sublimation of silicon atoms, which has produced wafer scale graphene that displays switching speeds of up to 100 GHz. The price of the SiC wafer required for this route is high relative to a Si wafer, limiting its use to devices where excellent performance of the device justifies the wafer cost. A promising approach is the relatively inexpensive deposition of graphene by chemical vapor deposition (CVD) onto a transition metal substrate, such Ni, Pd, Ru, Ir or Cu, where uniform single layer deposition of graphene on copper foils has occurred over large areas. CVD deposited graphene, on copper, has been of sufficient quality to demonstrate mobilities of up to 7,350 cm²V⁻¹s⁻¹ where low temperature deposition produced large areas.

In spite of the exceptional thermal and chemical stability of graphene, its use as a diffusion barrier for metals on semiconductors has not been examined. The mitigation of interdiffusion of contact metals or diffusion into and reaction of the metals with an underlying semiconductor during thermal processing and operation of a semiconductor device is required for high device reliability. The incorporation of graphene diffusion barriers may also add flexibility when designing process schemes to integrate graphene as a channel material on existing semiconductors.

### BRIEF SUMMARY

Embodiments of the invention are directed to contacts in electronic packaging where a first layer comprising a conductor and a second layer comprising a second conductor or a semiconductor is separated by a barrier layer comprising graphene. Other embodiments of the invention are directed to semiconductor devices comprising a contact that has the first and second layer separated by a barrier layer comprising graphene. The conductors used for the first and second layers can be metals, metal alloys, or even doped metal oxides or conductive carbons. Metals such as Al, Au, Cu, Ni, Pt, Ta, or Ti can be used. The second layer can be a semiconductor such as Si, Ge, SiC, GaN, GaAs, or an organic semiconductor. The graphene barrier layer can be as few as one graphene sheet in thickness, or it can be as many as ten graphene sheets in thickness. In embodiments of the invention, the barrier layer can be one to three graphene sheets in thickness. The contact can have additional layers. In an embodiment of the invention, a semiconductor can comprise a third layer when the second layer is a conductor, and a second barrier layer comprising graphene can be situated between the second and third layer if desired.

Another embodiment of the invention is a method to prepare a contact of a semiconductor device where a graphene barrier layer is deposited on a second layer and a first layer is deposited on the barrier layer. In one embodiment of the invention, the barrier layer can be deposited by forming graphene on a template layer, generating a binding layer to secure the graphene, forming a trilayer structure, and transferring the graphene face of a bilayer structure, generated upon removal of the template layer, on the second layer. The template layer can be a metal layer that is sacrificial and the binding layer is an organic polymer that can be removed by dissolving or decomposing after placement of the graphene on the second layer. The graphene layer can be formed by chemical vapor deposition (CVD) of the template layer. The template layer can be patterned such that a patterned graphene layer can be prepared.

### BRIEF DESCRIPTION OF DRAWINGS

FIG. 1 shows a Micro-Raman spectrum of graphene barrier layer transferred to a second layer substrate, according to an embodiment of the invention, where the G and 2D signals indicate that the barrier layer is a bilayer.

FIG. 2 shows scanning electron microscopy (SEM) images of the top surfaces of (a) an Al/Si contact and (b) an Al/graphene/Si contact, according to an embodiment of the invention, after annealing at 700° C.

FIG. 3 shows cross section SEM views of an Al spike formed in an Al/Si contact annealed at (a) 600° C. and (b) 700° C.

FIG. 4 shows cross section SEM views of (a) an Al/Si contact and (b) an Al/graphene/Si contact, according to an embodiment of the invention, after annealing at 600° C.

FIG. 5 shows microscopy (SEM) images of the top surfaces of (a) an Au/Ni/Si contact and (b) an Au/graphene/Ni/Si contact, according to an embodiment of the invention, after annealing at 500, 600 or 700° C.

FIG. 6 shows Nomarski optical micrograph images of an Au/graphene/Ni/Si contact, according to an embodiment of the invention, annealed at (a) 500, (b) 600 or (c) 700° C. and (d) an Au/Ni/Si contact annealed at 700° C.

FIG. 7 shows cross section SEM images of (a) a Au/Ni/Si contact and (b) a Au/graphene/Ni/Si contact, according to an embodiment of the invention, annealed at 500° C. (top row) and 600° C. (bottom row).

FIG. 8 shows a cross section SEM image of a Au/graphene/Ni/Si contact, according to an embodiment of the invention, anealed at (a) 700° C. and cross section EDS images showing the (b) Au, (c) Ni and (d) Si distribution.

FIG. 9 shows a cross section SEM image of an Au//Ni/Si contact annealed at 700° C. (A) and cross section EDS images showing the (b) Au, (c) Ni and (d) Si distribution.

### DETAILED DISCLOSURE

An embodiment of the invention is directed to contacts within an electronic package, for example, a semiconductor device, where a barrier layer comprising graphene is situated between a first layer comprising a conductor and a second layer comprising a conductor or a semiconductor. In embodiments of the invention, the first layer is a conductor comprising a metal, a metal alloy, or other conductor, for example, a doped metal oxide, or conductive carbon, for example, single walled carbon nanotubes or doped carbon nanotubes. The second layer can be a conductor, different from the conductor of the first layer, and can comprise a metal, metal alloy, or other conductor, for example, a doped metal oxide, or conductive carbon. The second layer can be a semiconductor, for example, Si, Ge, SiC, GaN, GaAs, or an organic semiconductor. The semiconductor can be a p or n-doped semiconductor. Metals that can comprise the first or second layers non-exclusively include Al, Au, Cu, Ni, Pt, Ta, and Ti. The graphene can comprise 1 to 3 sheets of graphene, or more, for example, 1 to 10 sheets, such that the average thickness of the barrier layer is the equivalent of 1 to 3 or more graphene sheets of graphite over the contact region in the electronic package. The barrier layer restricts diffusion and reaction between the first and second layer. The diffusion of layers, and any subsequent reaction, is restricted over a large range of temperatures, up to 700° C. or more in many cases, which inhibits diffusion during fabrication and/or use of the electronic packaging. Where the contact comprises two or more conducting layers, for example, two different metals, that are stacked on a semiconductor layer, the barrier layer may be situated between the two metals comprising the first and second layers, and the semiconductor comprising layer is a third layer, according to an embodiment of the invention. In an embodiment of the invention, a first barrier layer, referred to herein as a barrier layer, may exist between the first and second layers, where the second layer is a conductor different from the first layer, and a second barrier layer comprising graphene can separate the second layer from a third layer comprising a semiconductor.

In an exemplary embodiment of the invention, the barrier layer is situated between two conductors, for example, between a first layer of Al and a second layer of Ni. In another exemplary embodiment of the invention, the barrier layer is situated between a first layer of Al and a second layer of Si. Aluminum is soluble in Si at a level of 0.5-1 atom % at 450° C. and the activation energy for diffusion is low, only 0.79 eV. Formation of Al spikes into Si while annealing a device, to reduce native oxide and improve contact resistance, creates pits under contact regions after etching for a device where no graphene barrier layer exists. To reduce these effects, Si—Al or Al—Cu alloys have been used or a diffusion barrier has been inserted. Ni/Au is a common overlayer for Cu soldering pads in ball-grid-arrays (BGAs) and other electronic packages. In these packages, the Au layer is applied for oxidation protection and the Ni layer serves as a solderable diffusion barrier. Ni/Au is a common Ohmic contact metallization for p-type GaN. In all these applications, reactions of Al with Si or Au with Ni are undesirable but can occur, particularly at elevated temperatures that can occur during fabrication or use of the package. By inclusion of a graphene barrier layer, enhanced device reliability is possible.

In embodiments of the invention, the graphene barrier layer can be used between a first layer of Cu and a second layer of Si, to improve the reliability of contacts that presently are designed to have TiN, TaN or W barriers between Cu and Si. In other embodiments of the invention the barrier layer comprising graphene can be situated between a first layer of Cu and a second layer of Ti or Ta. In other embodiments of the invention, a graphene barrier layer can be placed between an aluminum first layer and a second layer that comprises Si, where the face of the Si that is adjacent the barrier layer has been modified to have a semiconducting silicide structure, for example, a metal silicide, such as Pd₂Si, PtSi₂, TiSi₂, MoSi₂, WSi₂, CoSi₂, or NiSi₂.

Other embodiments of the invention are directed to GaAs comprising semiconductor devices. Contacts for some current GaAs based devices comprise a gate metal stack of Ti/Pt/Au. According to an embodiment of the invention, a gate stack where the first layer of the contact is Ti and the second layer of the contact is Au can be constructed with a barrier layer of graphene.

Other embodiments are directed to GaN comprising semiconductor devices. Contacts for some current GaN based devices comprise a gate metal stack of Pt/Ti/Au. According to an embodiment of the invention a gate stack where the first layer of the contact is Pt and the second layer of the contact is Au can be constructed with a barrier layer of graphene. Ohmic contacts for some current GaN based devices comprise an ohmic metal stack of Ti/Al/Ni/Au. In embodiments of the invention, an ohmic metal stack for a device comprising a third layer of GaN has a first layer of Al and a second layer of Au separated by a graphene barrier layer, where the first layer has been coated with Ti on the face opposite the graphene barrier layer.

Another embodiment of the invention is directed to the formation of a graphene barrier layer between a first layer, where the first layer is a conductor, and a second layer that is a conductor, different from the conductor of the first layer, and can comprise a metal, metal alloy, or other conductor, for example, a doped metal oxide, or conductive carbon, or the second layer is a semiconductor, for example, Si, Ge, SiC, GaN, GaAs, or an organic semiconductor. The diffusion barrier is prepared by the formation of a layer of graphene on a template layer, for example, a metal surface, and forming binding layer, for example, an organic polymer layer, on the graphene to form an organic polymer/graphene/metal trilayer structure. Removal of the template layer results in a bilayer structure, which can be used to transfer the graphene layer to the second layer to form the barrier layer of the contact after removal of the binding layer. For example, the metal of the trilayer structure can be removed by exposure of the metal to a strong oxidizing solution that dissolves the resulting oxidized metal salt. An exemplary oxidizing solution is a dilute ammonium persulfate (H₈N₂O₈S₂) solution, but other oxidizing solutions, for example, a FeCl₃ solution can be used for the oxidation of the metal. The organic polymer, for example, a polymethylmethacrylate (PMMA) layer, of the remaining organic polymer/graphene bilayer structure, can be transferred to a substrate comprising the second layer of the contact, for example, a semiconductor substrate or a metal substrate, such that the second layer contacts the graphene barrier layer. Other organic polymers that can be used include, but are not limited to, polydimethylsiloxane or polystyrene. Upon placement of the bilayer on the surface of the conductor or semiconductor that becomes the second layer of the contact with the graphene face of the bilayer contacting the surface, the organic polymer is removed by dissolving the polymer in a solvent, chemical degradation of the polymer, or physical degradation, for example, thermolysis, of the polymer. The contact is completed by depositing a conductor on the freshly exposed graphene face by a metallization or other process to form the first layer of the contact adjacent to the graphene barrier layer.

According to an embodiment of the invention, a semiconductor device comprising a contact having a graphene diffusion layer situated between a first layer comprising a conductor and a second layer comprising a conductor or a semiconductor layer, can undergo thermal stress without formation of defects due to migration of a first metal into a second metal or a metal into a semiconductor. Prior to contacting the graphene of the organic polymer/graphene bilayer to a conductor or semiconductor surface, or after transfer of the graphene layer from the bilayer to a metal or semiconductor surface, the graphene can be patterned. For example, prior to forming the organic polymer/graphene bilayer, the graphene layer can be formed to have a pattern imposed by a patterned metal template layer, such that when the metal of the organic polymer/graphene/metal trilayer structure is removed by oxidation, the graphene layer is patterned such that it can be positioned on the conductor or semiconductor that comprises the second layer of the contact with a desired orientation. For example, a metal can be deposited with a pattern on a insulator, for example, SiO₂, or an insulator can be patterned on a metal, prior to deposition of the graphene on the metal, where the insulator is removed before, during, or after the removal of the metal from the trilayer structure. Alternately, the graphene can be cut to form a pattern, for example, graphene can be cut using 30 kV helium ions from a modified helium ion microscope.

### METHODS AND MATERIALS

### Al/graphene/Si

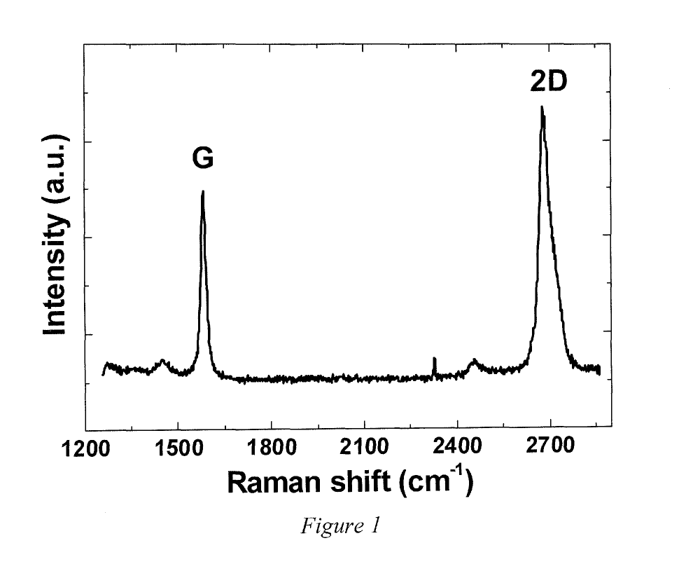

Graphene was grown on 25 μm thick Cu foil using the CVD method. Subsequently, polymethylmethacrylate (PMMA) was coated on the exposed grapheme surface to yield a PMMA/graphene/Cu-foil tri-layered structure. The layered structure was placed in a diluted ammonium persulfate (H₈N₂O₈S₂) solution, which exclusively etched the Cu-foil from the layered structure. The resulting PMMA/graphene bilayer structure was transferred to a Si substrate. The PMMA layer was dissolved using acetone. The graphene layer was characterized using Micro-Raman Spectroscopy (532 nm wavelength, single-mode DPSS laser, Omicron). The Raman spectrum of suspended graphene is shown in FIG. 1, which displays the characteristic G-peak and 2D-peak of graphene. The ratio of G/2D-peak indicates that the thickness of the suspended graphene was approximately that of a bilayer.

The graphene on the Si substrate was metalized with Al to create an Al/graphene/Si layered contact. Samples of the layered contact were annealed to temperatures as high as 700° C. for 5 minutes under an Ar atmosphere. The interdiffusion of layers in these samples was monitored by plan view and cross-sectional Scanning Electron Microscopy (SEM) and Energy Dispersive Spectrometry (EDS).

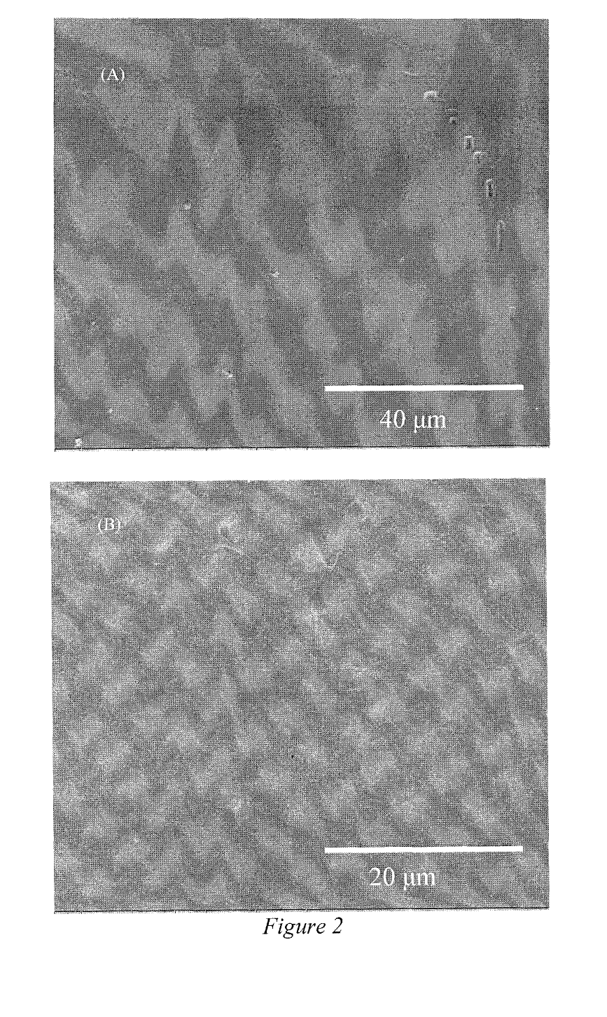

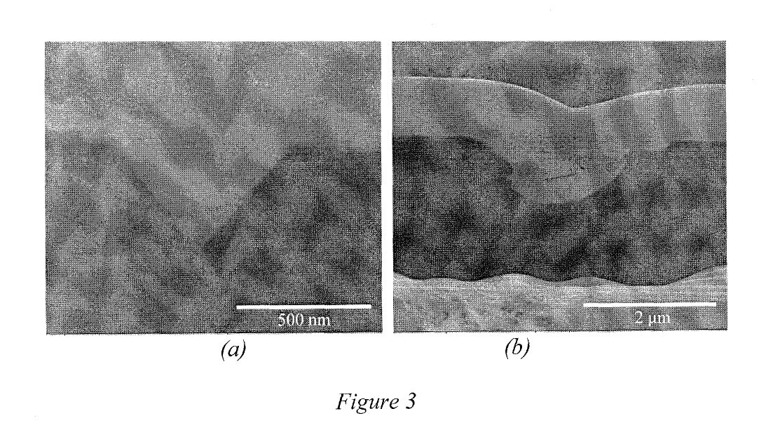

FIG. 2 shows plane (top) view SEM micrographs of the Al/Si (a) and Al/graphene/Si (b) structures after annealing at 700° C. The formation of pits around the edge of the metalized region is obvious in the micrographs of the Al/Si contact. A cross sectional SEM view of an Al/Si structure annealed at 600° C. displays an Al spike, as shown in FIG. 3, with a vertical penetration depth of approximately 500 nm. Similar images on samples annealed at 700° C. showed penetration depths of nearly 1 μm. The Al—Si system is a simple binary eutectic with limited solubility of aluminum in silicon and limited solubility of silicon in aluminum. The solubility of silicon in aluminum reaches a maximum 1.5 atom % at the eutectic temperature, and the solubility of silicon in aluminum increases with temperature to 0.016% Si at 1190° C. Therefore, the observed spikes are Al—Si eutectic phases.

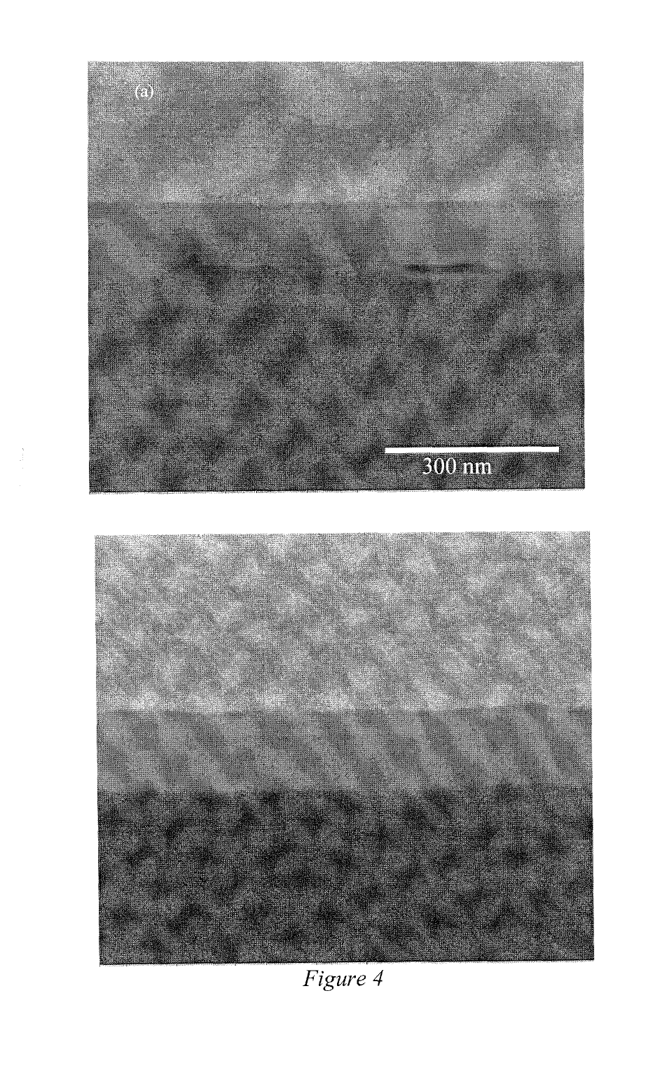

FIG. 4 shows interfaces of the Al/Si and Al/graphene/Si structures after annealing at 600° C. These SEM cross sections show a reacted interface between the Al and the Si at this temperature, whereas the presence of the graphene diffusion barrier prevents interaction of the Al and Si. The graphene was effective in reducing this interaction to at least 700° C.

### Au/graphene/Ni

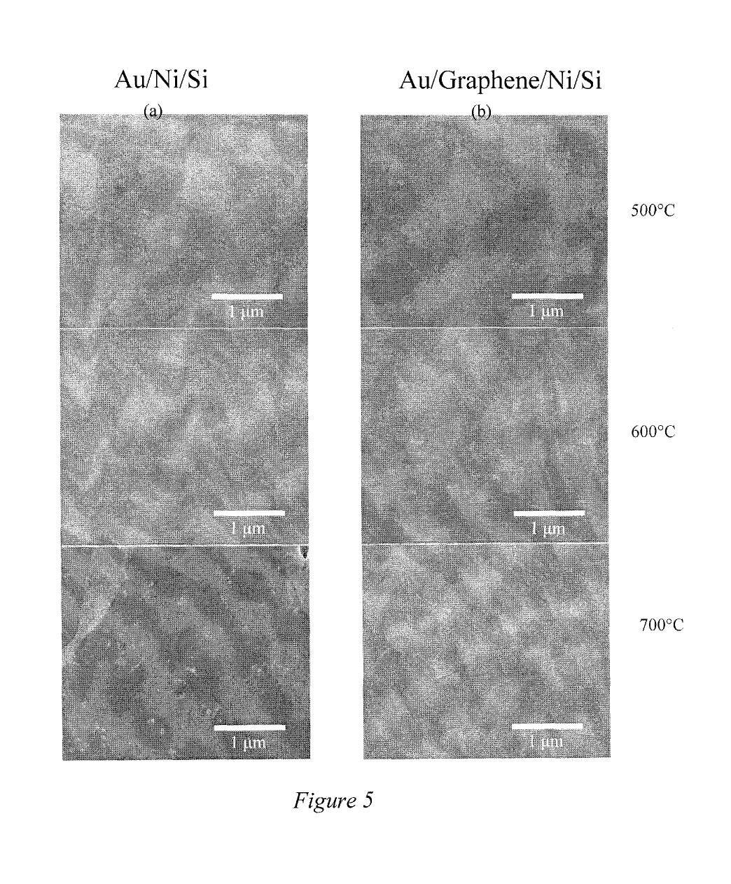

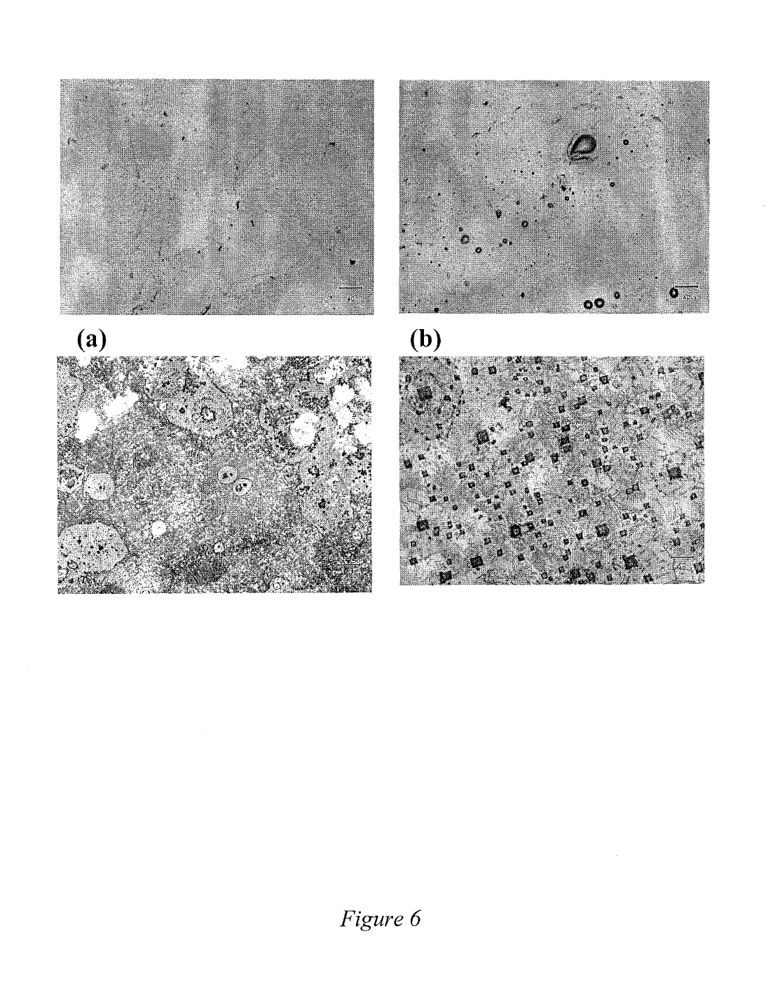

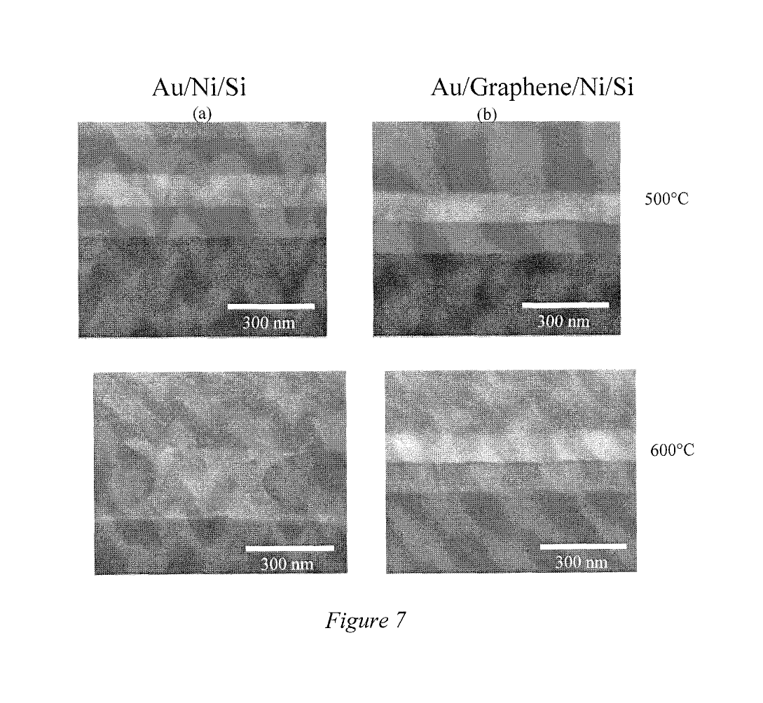

In the manner that a PMMA/graphene bilayer structure was used to deposit graphene on Si, the bilayer was used to deposit graphene on a nickel surface that was resistively evaporated on a Si substrate, a third layer. After removal of the PMMA layer and deposition of gold, an Au/graphene/Ni structure was formed. There was no metal migration between the Au and Ni at 600° C., as indicted in the plan view SEM micrographs shown in FIG. 5. At 700° C., there was evidence of the onset of diffusion, as can be seen in the Nomarski contrast images of FIG. 6. Although some interdiffusion occurs, SEM cross sections, shown in FIG. 7, indicate much less interdiffusion than that which occurs absent the graphene, which displays Au spikes through the Ni to the Si substrate. Such spikes are absent in the Au/graphene/Ni/Si structure annealed at 700° C.

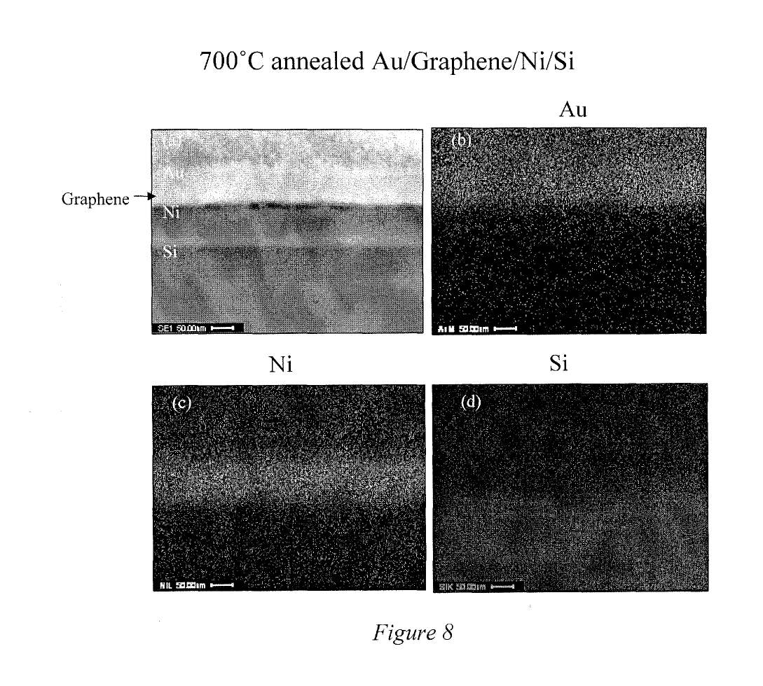

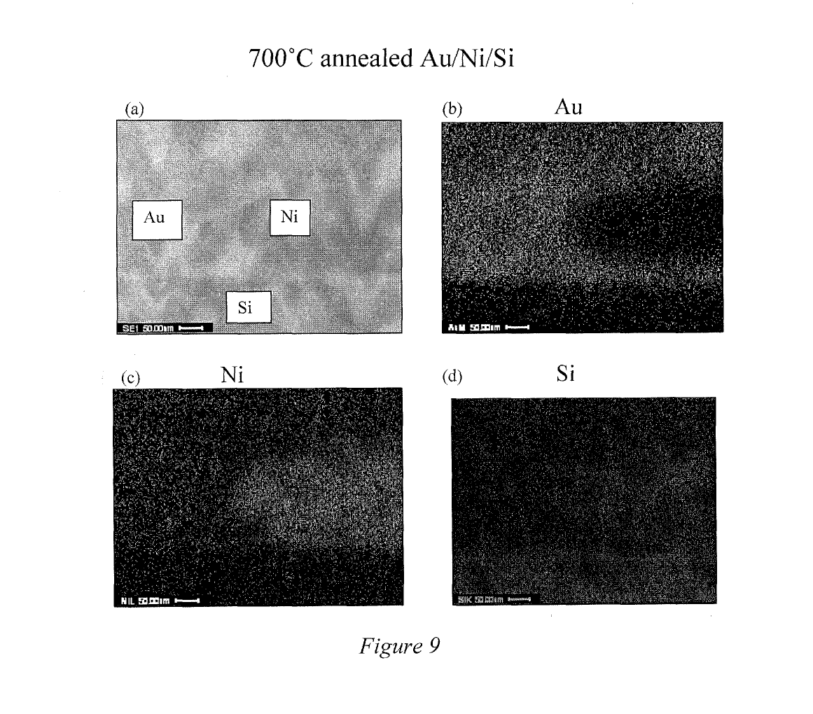

Samples annealed at 700° C. were examined by EDS. FIG. 8 shows an SEM image of the annealed structure, and the elemental maps of Au, Ni and Si obtained from EDS. The overall layer structure of the contact remains basically intact, with the individual metal layers clearly delineated even though the SEM plane views show that some reaction had occurred. In contrast, as shown in FIG. 9, an Au/Ni/Si structure lacking the graphene layer and annealed at 700° C. displays Au spikes through the Ni to the Si substrate and Si intermixing with the Ni.

It should be understood that the examples and embodiments described herein are for illustrative purposes only and that various modifications or changes in light thereof will be suggested to persons skilled in the art and are to be included within the spirit and purview of this application.

1. A contact of an electronic package, comprising:
a first layer comprising a conductor;
a second layer comprising a second conductor or a semiconductor; and
a barrier layer comprising graphene, wherein the barrier layer separates the first layer and the second layer.

2. The contact of claim 1, wherein the first layer comprises a metal, metal alloy, doped metal oxide, or conductive carbon.

3. The contact of claim 1, wherein the second layer comprises a metal, metal alloy, doped metal oxide, or conductive carbon.

4. The contact of claim 1, wherein the second layer comprises Si, Ge, SiC, GaN, GaAs, or an organic semiconductor.

5. The contact of claim 1, wherein the barrier layer comprises 1 to 3 sheets of graphene.

6. The contact of claim 1, wherein the first layer comprises Al and the second layer comprises Si.

7. The contact of claim 1, wherein the first layer comprises Au and the second layer comprises Ni.

8. The contact of claim 1, further comprising a third layer comprising a semiconductor, and, optionally, comprising a second barrier layer comprising graphene separating the second layer and the third layer, wherein the second layer is a conductor.

9. The contact of claim 1, wherein the first layer comprises Au, the second layer comprises Ni, and the third layer comprises Si.

10. The contact of claim 1, wherein the first layer comprises Al, Au, Cu, Ni, Pt, Ta, or Ti.

11. The contact of claim 1, wherein the second layer comprises Al, Au, Cu, Ni, Pt, Ta, or Ti.

12. A semiconductor device, comprising at least one contact according to claim 1.

13. A method to prepare a contact of a semiconductor device according to claim 1, comprising:
providing a second layer comprising a second conductor or a semiconductor;
depositing a barrier layer comprising graphene on the second layer; and
depositing a first layer comprising a conductor on the barrier layer.

14. The method of claim 13, wherein depositing a barrier layer comprises:
providing a graphene layer; and
transferring the graphene layer to a face of the second layer.

15. The method of claim 14, wherein providing a graphene layer comprises:
providing a template layer;
growing the graphene layer on the template layer;
forming a binding layer on the graphene layer, opposite the template layer; and
removing the template layer, wherein the graphene layer is supported by the binding layer in a bilayer structure.

16. The method of claim 15, wherein transferring comprises:
placing the bilayer structure on the second layer, wherein the graphene layer contacts the second layer upon placement; and
removing the binding layer, wherein the graphene layer resides on the second layer.

17. The method of claim 15, wherein the template layer is a metal and the binder layer is an organic polymer.

18. The method of claim 17, wherein the template layer is Cu or Ni.

19. The method of claim 15, wherein removing the binding layer comprises dissolving the organic polymer, chemically decomposing the polymer, or physically decomposing the polymer.

20. The method of claim 15, wherein the template layer is patterned and wherein the graphene layer has the pattern of the template layer.

21. The method of claim 15, wherein growing the graphene layer comprises chemical vapor deposition of graphene on the template layer.

22. The method of claim 13, wherein depositing the barrier layer comprises chemical vapor deposition of graphene, and wherein the second layer templates the formation of the barrier layer.
